(19) United States
(12) Patent Application Publication
(10) Pub. No.: US 2001/0006457 A1
(43) Pub. Date: Jul. 5, 2001

(54) Printed-circuit board and method of mounting electric components thereon

(76) Inventor: Satsuki Fujino, Tokyo, JP (US)

Correspondence Address: FLYNN, THIEL, BOUTELL & TANIS, P.C., 2026 Rambling Road, Kalamazoo, MI, 49008-1699, US

(21) Appl. No.: 09/738,677

(22) Filed: Dec. 15, 2000

(30) Foreign Application Priority Data
Dec. 27, 1999 (JP) 11-371052

(51) Int. Cl. H05K 7/06; H05K 1/18

(52) U.S. Cl. 361/761

(57) ABSTRACT

It is an object of the invention is to reduce intervals between electric components mounted on a printed-circuit board by mounting the electric components on recessed portions formed on the printed-circuit board. It is another object of the invention to render an inductance as an electric property small by reducing the lengths of conductive patterns. To achieve these objects, bypass capacitors are mounted on the recessed portions that are formed by cutting one surface of the printed-circuit board, and an IC socket is mounted on one surface of the printed-circuit board, then the conductive patterns for connecting the IC socket 1 and metallic portions formed on both sides of the bypass capacitors are formed on one surface of the printed-circuit board.

### BACKGROUND OF THE INVENTION

1. Field of the Invention

The invention relates to a printed-circuit board that is used for a semiconductor tester for testing the property of an IC (integrated circuit) and a method of mounting electric components thereon.

2. Related Art

Electric components such as an IC socket, a capacitor and so forth are mounted on a printed-circuit board such as a DUT (device under test) board that is used for a semiconductor tester.

FIG. 3 is a view showing a state where an electric component is mounted on a conventional printed-circuit board 200. In FIG. 3, depicted by 1 is an IC socket, 200 is the printed-circuit board, 3 is a bypass capacitors, 400a and 400b are conductive patterns and 500 is solders.

A plurality of leads 11 of the IC socket 1 are inserted from one surface 200a of the printed-circuit board 200 into a plurality of through holes 200c that penetrate printed-circuit board in the direction of thickness of the printed-circuit board 200, and they are soldered onto the other surface 200b of the printed-circuit board 200, not shown.

The leads 11 of the IC socket 1 and conductive patterns 400a and 400b formed on the other surface 200b of the printed-circuit board 200 are electrically connected to each other by soldering.

Metallic portions 3a on both sides of each bypass capacitor 3 that is provided on the other surface 200b of the printed-circuit board 200 and conductive patterns 400b formed on the other surface 200b of the printed-circuit board 200 are electrically connected to each other by the solders 500.

FIG. 4 is a view showing a state where electric components mounted on conventional multi-layer printed-circuit boards 201, 202, 203. The constituted members which are the same as those shown in FIG. 3 are denoted by the same reference numerals.

A plurality of leads 11 of the IC socket 1 are inserted into a plurality of through holes 201c, 202c, 203c that penetrate the printed-circuit boards 201, 202, 203, and they are soldered onto the other surface 203b of the printed-circuit board 203, not shown.

Conductive patterns 401, 402a to 402e, 403a, 403b formed on the printed-circuit boards 201, 202, 203 are respectively connected to the leads 11 inserted into the through holes 201c, 202c, 203c. The conductive patterns 403b and 403c are electrically connected to each other by way of the through hole 203d.

Metallic portions 3a on both sides of each bypass capacitor 3 that is provided on the other surface 202b of the printed-circuit board 202 and the conductive pattern 402b formed on the other surface 202b of the printed-circuit board 202 are electrically connected to each other by solders 502.

However, in the conventional printed-circuit board and method of mounting electric components, if the bypass capacitors 3 are mounted on the printed-circuit boards 200, 202, the areas of the bypass capacitors 3 to be mounted become large because the areas occupied or needed by solders 500, 502 are large. Accordingly, even if the external size of each bypass capacitor 3 is reduced, there occurs a problem that the printed-circuit boards 200, 202 are not downsized.

Further, the conductive patterns 400b, 402b become long by the number of the solders 500, 502, an inductance as an electric property becomes large, resulting in a problem for rendering a noise reduction effect of the bypass capacitor 3 small.

### SUMMARY OF THE INVENTION

It is therefore an object of the invention to shorten intervals between electric components that are mounted on the printed-circuit board by mounting the electric components on recess portions formed on the printed-circuit board. It is another object of the invention to render an inductance as an electric property small by shortening the lengths of the conductive patterns.

To achieve the above objects, a printed-circuit board according to a first aspect of the invention is made of an insulating material and comprises conductive patterns formed thereon and a plurality of varieties of electric components mounted on the conductive patterns, and the printed-circuit board is characterized in further comprising recessed portions formed on the printed-circuit board by cutting the surface of the printed-circuit board conforming to the external configuration of predetermined electric components of the plurality of varieties of electric components, and the conductive patterns formed on the printed-circuit board and connecting the predetermined electric components mounted on the recessed portions and other electric components adjoining to the predetermined electric components.

The printed-circuit board according to a second aspect of the invention is characterized in that the recessed portions are formed conforming to the external configurations of the predetermined electric components at positions where the conductive patterns connect between the predetermined electric components mounted on the recessed portions and other electric components adjoining to the predetermined electric components at the shortest distance between the predetermined electric components and other electric components.

A method of mounting electric components on a printed-circuit board according to a third aspect of the invention wherein the printed-circuit board is made of an insulating material and comprises conductive patterns formed on the surface of the printed-circuit board and a plurality of varieties of electric components mounted on the conductive patterns, and the method is characterized in comprising the steps of forming recessed portions on the surface of the printed-circuit board by cutting the surface of the printed-circuit board conforming to the external configuration of predetermined electric components of the plurality of varieties of electric components, wherein the conductive patterns connect the predetermined electric components mounted on the recessed portions and other electric components adjoining to the predetermined electric components so as to mount a plurality of varieties of electric components on the conductive patterns.

The method of mounting electric components on a printed-circuit board according to a fourth aspect of the invention is characterized in that the recessed portions are formed at positions where the conductive patterns connect between the predetermined electric components mounted on the recessed portions and other electric components adjoining to the predetermined electric components at the shortest distance therebetween.

According to the printed-circuit board of the first and second aspects of the invention, and the method of mounting electric components on a printed-circuit board of the third and fourth aspects of the invention, since the predetermined electric components on the recessed portions formed on the printed-circuit board, the lengths of the conductive patterns for connecting one electric component to another electric component are reduced.

Accordingly, the length of the interval between the electric components to be mounted on the printed-circuit board can be reduced, thereby making the printed-circuit board downsize. Further, the reduction of the lengths of the conductive patterns can reduce an inductance as an electric property.

Still further, since the thickness of the printed-circuit board on which the predetermined electric components are mounted is reduced, the distance between respective printed-circuit boards of multi-layer printed-circuit boards. As a result, the multi-layer printed-circuit board can be downsized.

### BRIEF DESCRIPTION OF THE DRAWINGS

FIG. 1 is a view showing a state where electric components are mounted on a printed-circuit board according to a first embodiment of the invention;

FIG. 2 is a view showing a state where electric components are mounted on multi-layer printed-circuit boards according to a second embodiment of the invention;

FIG. 3 is a view showing a state where electric components are mounted on a conventional printed-circuit board; and

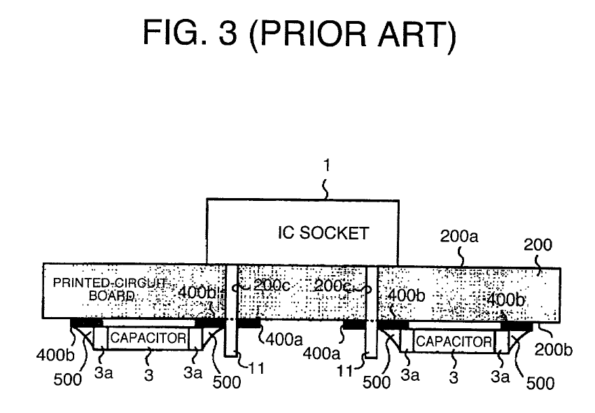

FIG. 4 is a view showing a state where electric components are mounted on conventional multi-layer printed-circuit boards.

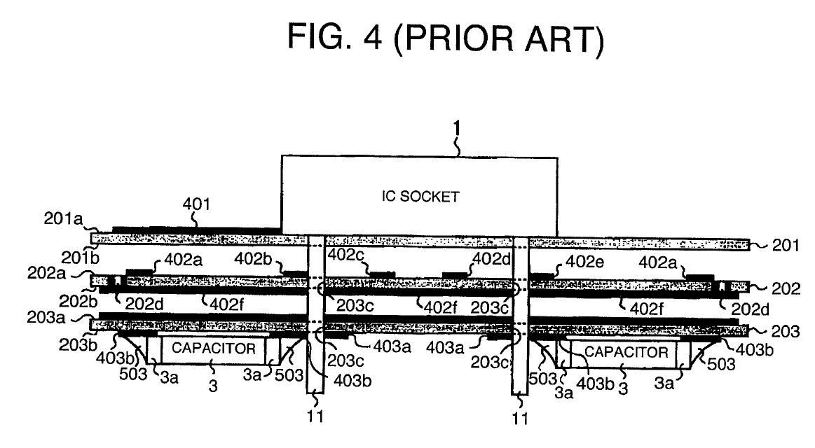

### PREFERRED EMBODIMENT OF THE INVENTION

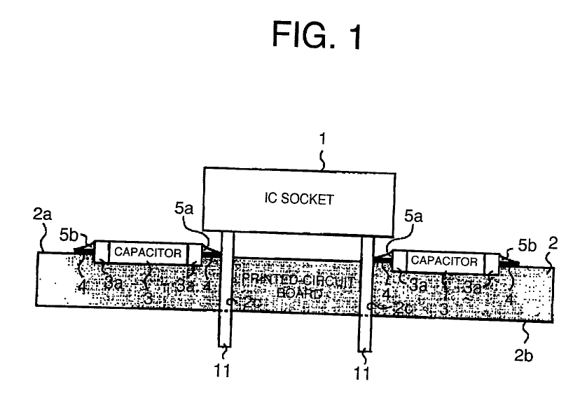

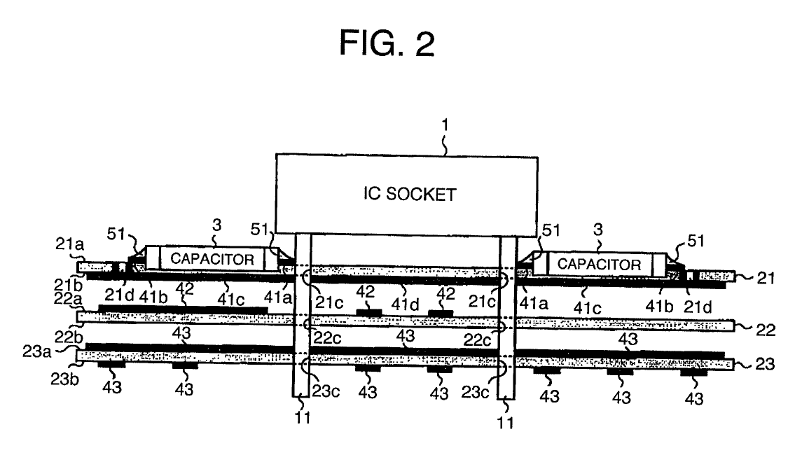

A printed board and method of mounting electric components thereon according to the first and second aspect of the invention is now described with reference to FIGS. 1 and 2.

FIG. 1 is a view showing a state where electric components are mounted on a printed-circuit board according to a first embodiment of the invention.

In FIG. 1, depicted by 1 is an IC socket, 2 is a printed-circuit board, 3 is bypass capacitors, 4 is conductive patterns and 5a, 5b are solders.

The IC socket 1 is a lead through component for mounting an IC to be tested thereon, and a plurality of leads 11 are inserted into a plurality of through holes 2c defined in the printed-circuit board 2 in the direction of thickness thereof and they are soldered onto the other surface 2b of the printed-circuit board 2.

The bypass capacitors 3 are mounted on recessed portions formed on one surface 2a of the printed-circuit board 2 at positions closest to the adjoining IC socket 1 conforming to the external configurations of the bypass capacitors 3. Further, the conductive patterns 4 formed on one surface 2a of the printed-circuit board 2 and the metallic portions 3a on both sides of the bypass capacitors 3 are connected to each other by solders 5a, 5b.

Further, the leads 11 of the printed-circuit board 1 are inserted into through holes 2c formed by penetrating the printed-circuit board 2, and they are soldered onto a back surface 2b of the printed-circuit board 2.

In this case, the IC socket 1 is mounted on the printed-circuit board 2 in a state where it is floated by the height of each bypass capacitor 3 conforming to the positions where the adjoining bypass capacitors 3 are mounted.

The bypass capacitors 3 are capacitors for removing a noise produced in the printed-circuit board 2 and they are mounted on the recessed portions provided on the one surface 2a of the printed-circuit board 2.

FIG. 2 is a view showing a state where electric components are mounted on multi-layer printed-circuit boards 21, 22, 23 according to a second embodiment of the invention.

As shown in FIG. 2, the printed-circuit boards 21, 22, 23 are provided to be multi-layer. A plurality of leads 11 of the IC socket 1 are inserted into a plurality of through holes 21c, 22c, 23c defined by penetrating the printed-circuit boards 21, 22, 23 and they are soldered onto the other surface 23b of the printed-circuit board 23, not shown.

Conductive patterns 41a to 41d, 42, 43 formed on the respective printed-circuit boards 21, 22, 23 are connected to one another by leads 11 that are inserted into the through holes 21c, 22c, 23c defined in the printed-circuit boards 21, 22, 23. Futher, in the printed-circuit boards 21, the conductive patterns 41b, 41c are electrically connected to each other by the through hole 21d.

The bypass capacitors 3 are mounted on recessed portions formed on one surface 21a of the printed-circuit board 21 at the positions closest to the adjoining IC socket 1 conforming to the external configurations of the bypass capacitors 3. The bypass capacitors 3 are capacitors for removing a noise produced in the printed-circuit board, and the metallic portions 3a on both sides of the bypass capacitors 3 and the conductive patterns 41a, 41b formed on one surface 22a of the printed-circuit board 21 are connected to each other by solders 52.

In this case, the IC socket 1 is mounted on the printed-circuit boards in a state where it is floated by the height of each bypass capacitor 3 conforming to the position where the adjoining bypass capacitor 3 is mounted.

Subsequently, the method of mounting electric components on the printed-circuit board 2 is described with reference to FIGS. 1 and 2.

First of all, the printed-circuit board 2 is prepared, wherein the printed-circuit board 2 is vertically penetrated to form the through holes 2c and the recessed portions, not shown, conforming to the external configurations of the bypass capacitors 3 are formed on one surface 2a of the printed-circuit board 2, and the conductive patterns 4 are formed on the one surface 2a of the printed-circuit board 2.

The bypass capacitors 3 are embedded in the recessed portions of the printed-circuit board 2 and the metallic portions 3a on both sides of the bypass capacitors 3 and the conductive patterns 4 formed on the printed-circuit board 2 are connected to each other by the solders 5a, 5b.

Then, the leads 11 are inserted into the through holes 2c and they are soldered on the other surface 2b of the printed-circuit board 2.

In such a manner, the bypass capacitors 3 are mounted on one surface 2a of the printed-circuit board 2 and the IC socket 1 is mounted on one surface 2a of the printed-circuit board 2 in a state where it is slightly floated therefrom.

Subsequently, the method of mounting electric components on the multi-layer printed-circuit board is described with reference to FIG. 2.

First of all, the printed-circuit boards 21, 22, 23 are prepared as shown in FIG. 2. A plurality of through holes 21c, 22c, 23c are defined in the printed-circuit boards 21, 22, 23 and the conductive patterns 41a to 41d, 42, 43 are formed on the circuit boards 21, 22, 23. The recessed portions corresponding to the external configuration of the bypass capacitor 3 are formed on one surface 21a of the printed-circuit board 21.

Bypass capacitors 3 are engaged in the recessed portions of the printed-circuit board 22, and the metallic portions 3a on both sides of the bypass capacitors 3 and the conductive patterns 41a, 41b formed on one surface 22a of printed-circuit board 22 are connected to each other by solders 51.

Then, the printed-circuit boards 21, 22, 23 are rendered multi-layer, and the leads 11 of the IC socket 1 are inserted from one surface 21a of the printed-circuit board 21 into the through holes 21c, 22c, 23c of the printed-circuit boards 21, 22, 23, then they are soldered onto the other surface 23b of the printed-circuit board 23.

In such a manner, the bypass capacitor 3 are mounted on one surface 22a of the printed-circuit board 22 and the bypass capacitor 3 are mounted on one surface 21a of the printed-circuit board 21.

According to the first embodiment of the invention, the recessed portions corresponding to the external configuration of the bypass capacitors 3 are formed on one surface 2a of the printed-circuit board 2, and the bypass capacitors 3 are engaged in the recessed portions. When the metallic portions 3a on both sides of the bypass capacitors 3 and the conductive patterns 4 formed on one surface 2a of the printed-circuit board 2 are connected to each other by the solders 5a, 5b, the bypass capacitors 3 are mounted on the one surface 2a of the printed-circuit board 2.

Further, when the leads 11 are inserted into the through holes 2c of the printed-circuit board 2 and they are soldered onto the other surface 2b of the printed-circuit board 2, the IC socket 1 is mounted on the one surface 2a of the printed-circuit board 2 in a state where it is slightly floated therefrom.

In the case of the multi-layer printed-circuit boards 21, 22, 23 according to the second embodiment, likewise the printed-circuit board 2 according to the first embodiment as shown in FIG. 2, the recessed portions are formed on the printed-circuit board 21, and the bypass capacitors 3 are engaged in the recessed portions. When the metallic portions 3a on both sides of the bypass capacitors 3 and the conductive patterns 41a, 41b formed on the one surface 21a of the printed-circuit board 21 are connected to each other by the solders 51, the bypass capacitors 3 are mounted on the printed-circuit board 21.

Further, when the leads 11 are inserted into the through holes 21c, 22c, 23c of the printed-circuit boards 21, 22, 23 and they are soldered onto the other surface 23b of the printed-circuit board 23, the IC socket 1 is mounted on the one surface 21a of the printed-circuit board 21 in a state where it is slightly floated therefrom.

Accordingly, when the bypass capacitors 3 are mounted on the recessed portions of the printed-circuit boards 2, 21, areas needed for soldering (5a, 51) can be reduced, thereby reducing each interval between the bypass capacitors 3 and IC socket 1, so that both the printed-circuit boards 2, 21 can be downsized.

Since the lengths of the conductive patterns 4a, 41a for connecting the bypass capacitors 3 and IC socket 1 can be reduced, an inductance as an electric property is rendered small.

Further, when the bypass capacitors 3 are mounted on the recessed portions of the printed-circuit board 21, the thickness of the printed-circuit board 21 becomes thin, and hence the printed-circuit boards 21, 22, 23 can be downsized.

Still further, when the bypass capacitors 3 are mounted on the recessed portions of the printed-circuit boards 2, 21, each space defined between the IC socket 1 and one surface 2a, 21a of the printed-circuit boards 2, 21 can be utilized with high efficiency so that the each interval between the electric components mounted on the printed-circuit boards 2, 21 can be reduced, thereby downsizing the printed-circuit boards 2, 21.

The detail construction of the invention is not limited to the first and second embodiments but it can be varied appropriately to the extent not to deviate the gist of the invention. For example, in the multi-layer printed board, the positions of the printed-circuit boards on which the bypass capacitors 3 are mounted may be arbitrary. Further, supporting members for stabilizing the IC socket 1 in a state where it is slightly floated from each one surface 2a, 21a of the printed-circuit boards 2, 21 may be provided on the printed-circuit boards 2, 21.

The following effects can be attained by the invention. The lengths of the conductive patterns for connecting predetermined electric components and other electric components can be reduced by mounting the predetermined electric components on the recessed portions formed on the printed-circuit board. Accordingly, the interval between the electric components to be mounted on the printed-circuit board can be reduced, thereby downsizing the printed-circuit board.

Further, since the lengths of the conductive patterns can be reduced, an inductance as an electric property is rendered small.

Still further, since the thickness of each printed-circuit board on which predetermined electric components are mounted is reduced, the distance between each printed-circuit board in multi-layer printed-circuit boards can be reduced. As a result, the multi-layer printed-circuit board can be downsized.

What is claimed is:

1. A printed-circuit board made of an insulating material and comprising conductive patterns formed on the surface thereof and a plurality of varieties of electric components mounted on the conductive patterns, said printed-circuit board further comprising:
recessed portions formed on the printed-circuit board by cutting the surface of the printed-circuit board conforming to the external configuration of predetermined electric components of the plurality of varieties of electric components; and
said conductive patterns formed on the printed-circuit board and connecting the predetermined electric components mounted on the recessed portions and other electric components adjoining to the predetermined electric components.

2. The printed-circuit board according to claim 1, wherein said recessed portions are formed conforming to the external configurations of the predetermined electric components at positions where the conductive patterns connect between the predetermined electric components mounted on the recessed portions and other electric components adjoining to the predetermined electric components at the shortest distance therebetween.

3. A method of mounting electric components on a printed-circuit board made of an insulating material and comprising conductive patterns formed on the surface of the printed-circuit board and a plurality of varieties of electric components mounted on the conductive patterns, said method comprising the steps of:
forming recessed portions on the surface of the printed-circuit board by cutting the surface of the printed-circuit board conforming to the external configuration of predetermined electric components of the plurality of varieties of electric components; and
wherein said conductive patterns connect the predetermined electric components mounted on the recessed portions and other electric components adjoining to the predetermined electric components so as to mount a plurality of varieties of electric components on the conductive patterns.

4. The method of mounting electric components on a printed-circuit board according to claim 3, wherein said recessed portions are formed at positions where the conductive patterns connect between the predetermined electric components mounted on the recessed portions and other electric components adjoining to the predetermined electric components at the shortest distance therebetween.
